(19) United States
(12) Patent Application Publication
(10) Pub. No.: US 2026/0157190 A1
(43) Pub. Date: Jun. 4, 2026

(54) OPTICAL-ELECTRICAL INTEGRATED DEVICE

(71) Applicant: SHINKO ELECTRIC INDUSTRIES CO., LTD., Nagano (JP)

(72) Inventors: Yuji FURUTA, Nagano (JP); Hisashi KANEDA, Nagano (JP)

(21) Appl. No.: 19/403,603

(22) Filed: Nov. 28, 2025

(30) Foreign Application Priority Data
Dec. 2, 2024 (JP) 2024-209447

(51) Int. Cl. H10W 70/20; G02B 6/122; H10F 55/00; H10W 74/10

(52) U.S. Cl. CPC H10W 70/20; G02B 6/122; H10F 55/00; H10W 74/114

(57) ABSTRACT

An optical-electrical integrated device includes a first board, a second board facing a first region of the first board and coupled to the first board via a connecting member disposed in the first region, a semiconductor device mounted on the first or second board, an encapsulating resin filled between the first region and the second board to cover the connecting member and the semiconductor device, a PIC mounted on a side of the second board opposite from the first board and coupled to the semiconductor device, an optical component disposed adjacent to the PIC on a second region of the first board not facing the second board and enabling transmission and reception of optical signals to and from the PIC, and a bonding material disposed between each of the PIC and the encapsulating resin and the optical component to bond the PIC, the optical component, and the encapsulating resin together.

### CROSS-REFERENCE TO RELATED APPLICATIONS

This application is based upon and claims priority to Japanese Patent Application No. 2024-209447, filed on Dec. 2, 2024, the entire contents of which are incorporated herein by reference.

### FIELD

Certain aspects of the embodiments discussed herein are related to optical-electrical integrated devices. The optical-electrical integrated devices are sometimes also referred to as optoelectronic hybrid modules.

### BACKGROUND

In a data center or the like where various computers and devices for data communication or the like are installed, an optical coupling structure for connecting an optical waveguide device and an optical fiber or the like may be used. An example of such an optical coupling structure includes an optical coupling component using a planar lightwave circuit that is bonded and fixed to end surfaces of input/output waveguides of the optical waveguide device, and the optical waveguide device and the optical fiber are optically coupled via the planar lightwave circuit (refer to Japanese Laid-Open Patent Publication No. 2020-64211, for example).

In the optical coupling structure described above, the optical waveguide device and the optical coupling component are bonded and fixed to each other via a small bonding area, and thus, a bonding or adhesive strength between the optical waveguide device and the optical coupling component is weak. For this reason, when stress is applied to a coupling part between the optical waveguide device and the optical coupling component, a fracture may occur between the optical waveguide device and the optical coupling component, and a reliability of the optical coupling may deteriorate.

### SUMMARY

Accordingly, it is an object in one aspect of the embodiments to provide an optical-electrical integrated device having an optical coupling structure with a high reliability of optical coupling.

According to one aspect of the embodiments, an optical-electrical integrated device includes a first wiring board; a second wiring board facing a first region of the first wiring board and electrically connected to the first wiring board via a connecting member disposed in the first region; a semiconductor device mounted on the first wiring board or the second wiring board; an encapsulating resin filled between the first region of the first wiring board and the second wiring board to cover the connecting member and the semiconductor device; a photonic integrated circuit mounted on a side of the second wiring board opposite from the first wiring board and electrically connected to the semiconductor device; an optical component, disposed adjacent to the photonic integrated circuit on a second region of the first wiring board not facing the second wiring board, and configured to enable transmission and reception of optical signals to and from the photonic integrated circuit; and a first bonding material, disposed between the photonic integrated circuit and the optical component and between the encapsulating resin and the optical component, bonding the photonic integrated circuit, the optical component, and the encapsulating resin together, wherein the encapsulating resin extends from the first region to the second region, and a first side surface of the encapsulating resin bonded to the first bonding material is an inclined surface inclined toward an inside of the encapsulating resin in an upward direction from a lower surface of the encapsulating resin.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating an example of an optical-electrical integrated device according to a first embodiment;

FIG. 2 is a plan view illustrating an example of a first wiring board constituting the optical-electrical integrated device according to the first embodiment;

FIG. 3 is a cross sectional view illustrating an application example of the optical-electrical integrated device according to the first embodiment;

FIG. 4A and FIG. 4B are diagrams (part 1) illustrating examples of manufacturing processes of the optical-electrical integrated device according to the first embodiment;

FIG. 5A and FIG. 5B are diagrams (part 2) illustrating examples of manufacturing processes of the optical-electrical integrated device according to the first embodiment;

FIG. 6A and FIG. 6B are diagrams (part 3) illustrating examples of manufacturing processes of the optical-electrical integrated device according to the first embodiment;

FIG. 7A and FIG. 7B are cross sectional views illustrating an example of an optical-electrical integrated device according to a comparative example;

FIG. 8 is a cross sectional view illustrating an example of the optical-electrical integrated device according to a first modification of the first embodiment;

FIG. 9 is a cross sectional view illustrating an example of the optical-electrical integrated device according to a second modification of the first embodiment; and

FIG. 10 is a cross sectional view illustrating an example of the optical-electrical integrated device according to a third modification of the first embodiment.

### DESCRIPTION OF EMBODIMENTS

Hereinafter, embodiments of the present disclosure will be described with reference to the drawings. In the drawings, the same constituent elements are designated by the same reference numerals, and a redundant description thereof may be omitted.

### First Embodiment

### Configuration of Optical-Electrical Integrated Device

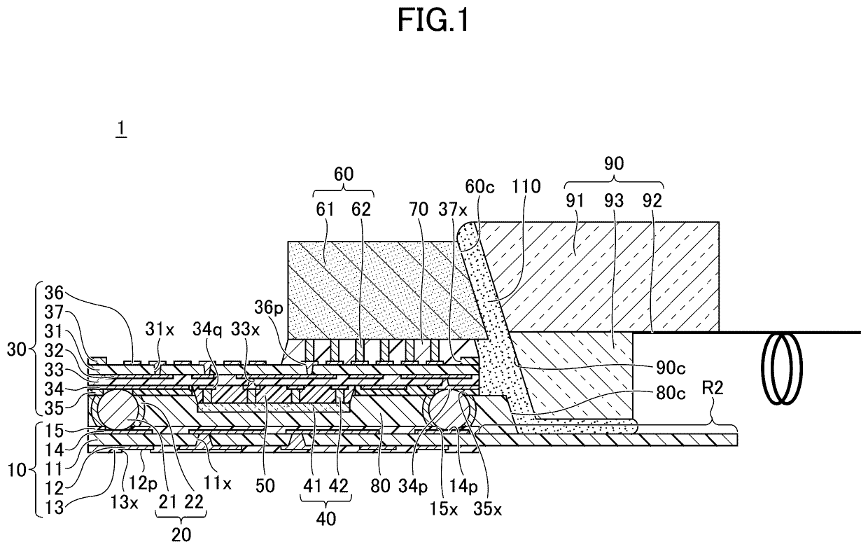

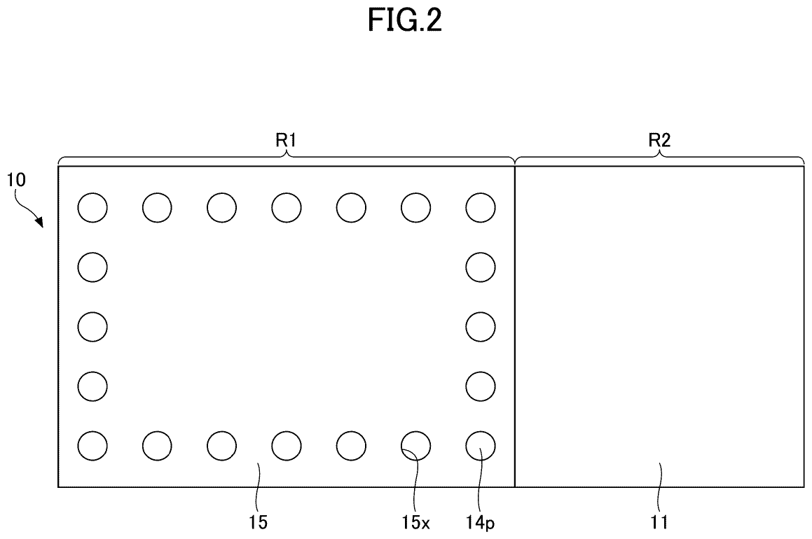

FIG. 1 is a cross sectional view illustrating an example of an optical-electrical integrated device according to a first embodiment. FIG. 2 is a plan view illustrating an example of a first wiring board constituting the optical-electrical integrated device according to the first embodiment. In FIG. 1, illustration of a leader line and a reference numeral for a first region R1 illustrated in FIG. 2 will be omitted for the sake of convenience and simplicity.

As illustrated in FIG. 1 and FIG. 2, an optical-electrical integrated device 1 includes a first wiring board 10, connecting members 20, a second wiring board 30, a semiconductor device 40, an underfill resin 50, a photonic integrated circuit (PIC) 60, an underfill resin 70, a encapsulating resin 80, a fiber array 90, and a first bonding material 110. The fiber array 90 is a typical example of an optical component according to the present invention. The first bonding material 110 is disposed between the PIC 60 and the fiber array 90, and between the encapsulating resin 80 and the fiber array 90, and bonds the PIC 60, the fiber array 90, and the encapsulating resin 80 together. The first bonding material 110 may further be disposed between the fiber array 90 and the second wiring board 30, and between the fiber array 90 and the underfill resin 70. An ultraviolet curable epoxy-based resin, a thermosetting epoxy-based resin, or the like can be used for the first bonding material 110.

In the optical-electrical integrated device 1, the first wiring board 10 includes the first region R1, and a second region R2 continuous with the first region R1. The second wiring board 30 faces the first region R1 of the first wiring board 10, and is electrically connected to the first wiring board 10 via the connecting members 20 disposed in the first region R1. In other words, in the first wiring board 10, a region facing the second wiring board 30 is the first region R1, and a region not facing the second wiring board 30 is the second region R2.

For example, the first wiring board 10 has a rectangular shape in a plan view, and the first region R1 and the second region R2 can be arranged adjacent to each other in a longitudinal direction of the rectangular shape. However, the arrangement of the first region R1 and the second region R2 is not limited to the arrangement illustrated in FIG. 2. For example, the second region R2 does not need to be disposed along an entirety of one side of the first region R1, and may be disposed along only a portion of one side of the first region R1.

In the present embodiment, for the sake of convenience, a side of the optical-electrical integrated device 1 provided with a solder resist layer 37 in FIG. 1 is referred to as an upper side or one side, and a side of the optical-electrical integrated device 1 provided with a solder resist layer 13 in FIG. 1 is referred to as a lower side or the other side. In addition, a surface of each part on the solder resist layer 37 side is referred to as one surface or an upper surface, and a surface of each part on the solder resist layer 13 side is referred to as the other surface or a lower surface. However, the optical-electrical integrated device 1 can be used in an upside-down state, or can be arranged at an arbitrary angle. Further, the term “plan view” refers to a view of an object in a normal direction to one surface of the solder resist layer 37, and the term “planar shape” refers to a shape of the object in the plan view viewed in the normal direction to the one surface of the solder resist layer 37.

The first wiring board 10 includes an insulating layer 11, an interconnect layer 12, the solder resist layer 13, an interconnect layer 14, and a solder resist layer 15.

In the first wiring board 10, a so-called glass epoxy substrate or the like in which a glass cloth is impregnated with an insulating resin, such as an epoxy-based resin or the like, can be used for the insulating layer 11, for example. A substrate or the like in which a woven fabric or a nonwoven fabric of glass fiber, carbon fiber, aramid fiber, or the like is impregnated with an insulating resin, such as the epoxy-based resin or the like, may be used for the insulating layer 11. A thickness of the insulating layer 11 may be in a range of approximately 60 μm to approximately 200 μm, for example. In each of the drawings, illustration of the glass cloth or the like is omitted.

The interconnect layer 12 is formed on a lower surface of the insulating layer 11. The interconnect layer 14 is formed on an upper surface of the insulating layer 11. The insulating layer 11 is formed with via holes 11x that penetrate the insulating layer 11 and expose a lower surface of the interconnect layer 14. The via holes 11x have a truncated cone shape such that a diameter (or area) of an opening of the via hole 11x that opens toward the solder resist layer 13 is larger than a diameter (or area) of a bottom surface of the via hole 11x formed by the lower surface of the interconnect layer 14. The opening of the via hole 11x may have a diameter of approximately 50 μm, for example.

The interconnect layer 12 includes a via interconnect filling an inside of the via hole 11x, and an interconnect pattern formed on the lower surface of the insulating layer 11. The lower surface of the interconnect layer 14 is in contact with an upper end portion of the via interconnect filling the inside of the via hole 11x of the interconnect layer 12. That is, the interconnect layer 12 is electrically connected to the interconnect layer 14.

A material used for the interconnect layer 12 may be copper (Cu) or the like, for example. A thickness of the interconnect pattern constituting the interconnect layer 12 may be in a range of approximately 10 μm to approximately 20 μm, for example. A material used for the interconnect layer 14 may be the same as the material used for the interconnect layer 12, for example. A thickness of the interconnect layer 14 may be the same as the thickness of the interconnect pattern constituting the interconnect layer 12, for example.

The solder resist layer 13 is formed on the lower surface of the insulating layer 11 to cover the interconnect layer 12. The solder resist layer 13 may be formed of a photosensitive resin or the like, for example. A thickness of the solder resist layer 13 may be in a range of approximately 15 μm to approximately 35 μm, for example. The solder resist layer 13 has openings 13x, and portions of the interconnect layer 12 are exposed inside the openings 13x. The portions of the interconnect layer 12 exposed inside the openings 13x constitute pads 12p. The pads 12p functions as pads electrically connected to a package substrate or the like.

The solder resist layer 13 may be provided so as to completely expose the pads 12p. In this case, the solder resist layer 13 may be provided so that an inner wall surface of the opening 13x and a side surface of the pad 12p are in contact with each other, or the solder resist layer 13 may be provided so that a gap is formed between the inner wall surface of the opening 13x and the side surface of the pad 12p.

If required, a metal layer may be formed on lower surfaces of the pads 12p, or an anti-oxidation treatment, such as an organic solderability preservative (OSP) treatment or the like, may be performed on the lower surfaces of the pads 12p. Examples of the metal layer include a gold (Au) layer, a nickel/gold (Ni/Au) layer (a metal layer in which a Ni layer and a Au layer are stacked in this order), a nickel/palladium/gold (Ni/Pd/Au) layer (a metal layer in which a Ni layer, a Pd layer, and a Au layer are stacked in this order), or the like. Further, external connection terminals, such as solder balls or the like, may be formed on the lower surfaces of the pads 12p.

The solder resist layer 15 is formed on the upper surface of the insulating layer 11 to cover the interconnect layer 14. A material used for and a thickness of the solder resist layer 15 may be the same as those of the solder resist layer 13, for example. The solder resist layer 15 has openings 15x, and portions of the interconnect layer 14 are exposed inside the openings 15x. The portions of the interconnect layer 14 exposed inside the openings 15x constitutes pads 14p. The pads 14p function as pads electrically connected to the connecting members 20. If required, the metal layer described above may be formed on upper surfaces of the pads 14p, or an anti-oxidation treatment, such as an OSP treatment or the like, may be performed on the upper surfaces of the pads 14p.

In the second region R2 of the example illustrated in FIG. 1 and FIG. 2, the lower surface of the insulating layer 11 is exposed from the solder resist layer 13, and the upper surface of the insulating layer 11 is exposed from the solder resist layer 15. However, the solder resist layer 13 and/or the solder resist layer 15 may extend from the first region R1 to the second region R2 and cover a portion or an entirety of the lower surface and/or the upper surface of the insulating layer 11.

The second wiring board 30 includes an insulating layer 31, an interconnect layer 32, an insulating layer 33, an interconnect layer 34, a solder resist layer 35, an interconnect layer 36, and the solder resist layer 37.

In the second wiring board 30, a material used for and a thickness of the insulating layer 31 may be the same as those of the insulating layer 11, for example. The interconnect layer 32 is formed on a lower surface of the insulating layer 31. A material used for the interconnect layer 32 may be the same as that of the interconnect layer 12, for example. A thickness of the interconnect layer 32 may be the same as that of the interconnect pattern constituting the interconnect layer 12, for example.

The insulating layer 33 is formed on the lower surface of the insulating layer 31 to cover the interconnect layer 32. A material used for the insulating layer 33 may be an insulating resin, such as a thermosetting epoxy-based resin or the like, for example. The insulating layer 33 may include a filler, such as silica (SiO₂) or the like. A thickness of the insulating layer 33 may be in a range of approximately 15 μm to approximately 35 μm, for example.

The interconnect layer 34 is formed on a lower surface of the insulating layer 33. The interconnect layer 34 includes a via interconnect filling an inside of a via hole 33x penetrating the insulating layer 33 and exposing a lower surface of the interconnect layer 32, and an interconnect pattern formed on the lower surface of the insulating layer 33.

The via hole 33x has a truncated cone shape such that a diameter (or area) of an opening of the via hole 33x that opens toward the solder resist layer 35 is larger than a diameter (or area) of a bottom surface of the via hole 33x formed by the lower surface of the interconnect layer 32. A material used for the interconnect layer 34 may be the same as that of the interconnect layer 12, for example. A thickness of the interconnect layer 34 may be the same as that of the interconnect pattern constituting the interconnect layer 12, for example.

The solder resist layer 35 is a protective insulating layer formed on the lower surface of the insulating layer 33 to cover the interconnect layer 34. A material used for and a thickness of the solder resist layer 35 may be the same as those of the solder resist layer 13, for example. The solder resist layer 35 has openings 35x, and portions of the interconnect layer 34 are exposed inside the openings 35x. The interconnect layer 34 exposed inside the openings 35x constitute pads 34p and 34q.

The pad 34p is disposed so as to face the pad 14p of the first wiring board 10. The pad 34p functions as pads to be bonded to the connecting members 20. The pad 34q functions as a pad to be bonded to the semiconductor device 40. A plurality of pads 34q are formed on the side of the second wiring board 30 closer to the first wiring board 10. Pad aperture diameters of the pads 34p electrically connected to the connecting members 20 and the pads 34q electrically connected to the semiconductor device 40 can be set independently. If required, the metal layer described above may be formed on lower surfaces of the pads 34p and 34q, or the anti-oxidation treatment, such as the OSP treatment or the like, may be performed on the lower surfaces of the pads 34p and 34q.

The interconnect layer 36 is formed on an upper surface of the insulating layer 31. The interconnect layer 36 includes a via interconnect filling an inside of a via hole 31x penetrating the insulating layer 31 and exposing an upper surface of the interconnect layer 32, and an interconnect pattern formed on the upper surface of the insulating layer 31.

The via hole 31x has an inverted truncated cone shape such that a diameter (or area) of an opening of the via hole 31x that opens toward the solder resist layer 37 is larger than a diameter (or area) of a bottom surface of the via hole 31x formed by the upper surface of the interconnect layer 32. A lower end portion of the via interconnect filling the inside of the via hole 31x of the interconnect layer 36 is in contact with the upper surface of the interconnect layer 32. That is, the interconnect layer 36 is electrically connected to the interconnect layer 32. A material used for the interconnect layer 36 and a thickness of the interconnect pattern constituting the interconnect layer 36 may be the same as those of the interconnect layer 12, for example.

The solder resist layer 37 is formed on the upper surface of the insulating layer 31 to cover the interconnect layer 36. A material used for and a thickness of the solder resist layer 37 may be the same as those of the solder resist layer 13, for example. The solder resist layer 37 has openings 37x, and portions of the interconnect layer 36 are exposed inside the openings 37x. The portions of the interconnect layer 36 exposed inside the opening 37x constitute pads 36p. The pads 36p function as pads to be bonded to the PIC 60. Some of the pads 36p may be used as pads for external connection. If required, the metal layer described above may be formed on upper surfaces of the pads 36p, or the anti-oxidation treatment, such as the OSP treatment or the like, may be performed on the upper surfaces of the pads 36p.

The semiconductor device 40 is mounted on the side of the first wiring board 10 closer to the second wiring board 30, or on the side of the second wiring board 30 closer to the first wiring board 10. In the example illustrated in FIG. 1, the semiconductor device 40 is mounted on the side of the second wiring board 30 closer to the first wiring board 10, and the semiconductor device 40 is electrically connected to the PIC 60 via the second wiring board 30. Specifically, the semiconductor device 40 is flip-chip mounted face-down on the lower surface of the second wiring board 30. The semiconductor device 40 includes a main body 41 provided with a semiconductor integrated circuit, and electrodes 42 serving as connection terminals. The electrodes 42 of the semiconductor device 40 are electrically connected to the pads 34q of the second wiring board 30 via solder or the like. Gold bumps, solder bumps, copper posts with solder coated tip ends, or the like can be used for the electrodes 42, for example.

The semiconductor device 40 is a semiconductor chip, for example. The semiconductor device 40 may be a semiconductor package with an insulating layer and a redistribution layer on the semiconductor chip. The first wiring board 10 and/or the second wiring board 30 may be mounted with a passive element, such as a capacitor, an inductor, a resistor, or the like, in addition to the semiconductor device 40.

The underfill resin 50 is filled between the semiconductor device 40 and the lower surface of the second wiring board 30. A material used for the underfill resin 50 is preferably has good flow properties. The material used for the underfill resin 50 may be an insulating resin, such as an epoxy-based resin or the like, for example.

The PIC 60 is mounted on the side of the second wiring board 30 opposite to the first wiring board 10, and is electrically connected to the semiconductor device 40. Specifically, the PIC 60 is flip-chip mounted face-down on the upper surface of the second wiring board 30. The PIC 60 includes a main body 61 including optical waveguides or the like, and electrodes 62 serving as connection terminals. The electrodes 62 of the PIC 60 are electrically connected to the pads 36p of the second wiring board 30 via solder or the like. Gold bumps, solder bumps, copper posts with solder coated tip ends, or the like can be used for the electrodes 62, for example.

The PIC 60 includes the optical waveguides, light emitting elements, light receiving elements, or the like provided on a substrate made of silicon or the like, for example. The PIC 60 may sometimes be referred to as silicon photonics or the like. The PIC 60 may have a function of converting an optical signal input from the fiber array 90 into an electrical signal and outputting the electrical signal to the semiconductor device 40 and/or a function of converting an electrical signal input from the semiconductor device 40 into an optical signal and outputting the optical signal to the fiber array 90.

A side surface 60c of the PIC 60, bonded to the first bonding material 110, is an inclined surface that is inclined toward an inside of the PIC 60 in an upward direction from a lower surface of the PIC 60. An angle formed by the lower surface and the side surface 60c of the PIC 60 may be 80° or greater and 85° or less, for example. The entire side surface 60c of the PIC 60 is preferably bonded to the first bonding material 110.

At least a portion of the PIC 60 preferably overlaps the semiconductor device 40 in the plan view. By this arrangement, the PIC 60 and the semiconductor device 40 can be connected via a short interconnect path, and thus, it is possible to transmit and receive a large amount of data at a high speed between the PIC 60 and the semiconductor device 40.

The semiconductor device 40 may have a function of amplifying an electrical signal input from the PIC 60. The electrical signal input from the PIC 60 is a high-speed signal and may easily become attenuated. For this reason, the PIC 60 and the semiconductor device 40 are connected via the short interconnect path, and the electrical signal that may become attenuated is amplified by the semiconductor device 40, to improve a quality of the electrical signal output from the semiconductor device 40.

The underfill resin 70 is filled between the PIC 60 and the upper surface of the second wiring board 30. The underfill resin 70 may be made of the same material as the underfill resin 50, for example.

The connecting members 20 are disposed between the pads 14p of the first wiring board 10 and the pads 34p of the second wiring board 30. The connecting members 20 have a function of electrically connecting the first wiring board 10 and the second wiring board 30, and securing a predetermined gap between the first wiring board 10 and the second wiring board 30.

In the present embodiment, as an example, solder balls with a core are used as the connecting members 20. Each connecting member 20 includes a substantially spherical core 21, and a conductive material 22 covering an outer peripheral surface of the core 21. Each core 21 is disposed so as to be in contact with the pad 14p and the pad 34p. A diameter of the core 21 before being bonded to the first wiring board 10 and the second wiring board 30 can be in a range of approximately 100 μm to approximately 300 μm, and is preferably approximately 200 μm, for example. A diameter of the entire connecting member 20 including the conductive material 22 before being bonded to the first wiring board 10 and the second wiring board 30 may be in a range of approximately 150 μm to approximately 350 μm, and is preferably approximately 250 μm, for example.

A metal core made of a metal such as copper or the like, a resin core made of a resin, or the like can be used for the core 21, for example. A solder material, such as an alloy including Pb, an alloy including Sn and Cu, an alloy including Sn and Sb, an alloy including Sn and Ag, an alloy including Sn, Ag, and Cu, or the like can be used for the conductive material 22, for example. The diameter of the core 21 can be determined by taking into consideration a height (or a thickness) of the semiconductor device 40.

The connecting members 20 are not limited to the solder balls with a core, including the core 21 and the conductive material 22 covering the outer peripheral surface of the core 21, and for example, solder balls or the like without a core may be used for the connecting members 20. In the case where the solder balls or the like without the core is used for the connecting members 20, a distance between the first wiring board 10 and the second wiring board 30 can be controlled using a predetermined jig at the time of manufacturing the optical-electrical integrated device 1. Alternatively, metal posts such as copper posts or the like, or metal bumps such as gold bumps or the like, may be used for the connecting members 20.

Although the connecting members 20 are illustrated in a simplified manner in FIG. 1, the connecting members 20 are actually arranged in multiple rows in a peripheral configuration, for example. In a case where the first wiring board 10 and the second wiring board 30 have a rectangular planar shape in the plan view, the connecting members 20 are provided in the peripheral configuration along peripheries of the wiring boards, for example. In a case where a diameter of the connecting members 20 is approximately 150 μm, a pitch of the connecting members 20 can be approximately 200 μm, for example.

The encapsulating resin 80 is filled between the first region R1 of the first wiring board 10 and the second wiring board 30, and covers the connecting members 20 and the semiconductor device 40. The encapsulating resin 80 extends from the first region R1 to the second region R2. A side surface 80c of the encapsulating resin 80, bonded to the first bonding material 110, is an inclined surface that is inclined toward an inside of the encapsulating resin 80 in an upward direction from a lower surface of the encapsulating resin 80.

An angle formed by the lower surface and the side surface 80c of the encapsulating resin 80 may be 80° or greater and 85° or less, for example. The angle formed by the lower surface and the side surface 80c of the encapsulating resin 80 is preferably within ±5°, more preferably within ±3°, and still more preferably within ±1° with respect to the angle formed by the lower surface and the side surface 60c of the PIC 60.

The side surface 80c of the encapsulating resin 80 and the side surface 60c of the PIC 60 may be parallel to each other. The side surface 80c of the encapsulating resin 80 and the side surface 60c of the PIC 60 lie on the same plane, for example. The side surface 80c of the encapsulating resin 80, the side surface 60c of the PIC 60, and a side surface 90c of the fiber array 90 may be parallel to one another. The entire side surface 80c of the encapsulating resin 80 is preferably bonded to the first bonding material 110.

A mold resin can be used for the encapsulating resin 80, for example. The mold resin is an insulating resin including a non-photosensitive thermosetting resin as a main component, which can be used in transfer molding, compression molding, injection molding, or the like. The mold resin is an insulating resin, such as a non-photosensitive thermosetting epoxy-based resin or the like, and may include a filler.

The fiber array 90 is an optical component that is disposed on the second region R2 of the first wiring board 10 that does not face the second wiring board 30, at a position adjacent to the PIC 60 via the first bonding material 110. The fiber array 90 enables transmission and reception of optical signals to and from the PIC 60. The fiber array 90 includes a base 91, a plurality of optical fibers 92, and a lid 93, for example. The base 91 and the lid 93 can be formed of glass or resin, for example. The base 91 has a plurality of elongated grooves in a surface facing the lid 93, for example. The grooves have a V-shaped cross section when cut perpendicularly to a longitudinal direction of the grooves, for example. Each optical fiber 92 is in contact with an upper surface of the lid 93 and an inner wall of the groove provided in the base 91. Thus, each optical fiber 92 is held between the base 91 and the lid 93. A thickness of the lid 93 may be less than a thickness of the base 91.

A gap between the fiber array 90 and the PIC 60 is approximately several tens of μm, for example. An end of each optical waveguide of the PIC 60 faces an end of each optical fiber 92 via the first bonding material 110. For this reason, each optical waveguide of the PIC 60 can transmit and receive an optical signal to and from each optical fiber 92. The first bonding material 110 is an optical adhesive having a high transmittance with respect to the wavelength of the optical signals transmitted and received between the fiber array 90 and the PIC 60, for example.

The side surface 90c of the fiber array 90, bonded to the first bonding material 110, is constituted by a side surface of the base 91 and a side surface of the lid 93. The side surface 90c of the fiber array 90 is an inclined surface that is inclined toward an outside of the fiber array 90 in an upward direction from a lower surface of the fiber array 90.

An angle formed by the upper surface and the side surface 90c of the fiber array 90 may be 80° or greater and 85° or less, for example. The angle formed by the upper surface and the side surface 90c of the fiber array 90 is preferably within ±5°, more preferably within ±3°, and still more preferably within ±1° with respect to the angle formed by the lower surface and the side surface 60c of the PIC 60.

The side surface 90c of the fiber array 90 may be parallel to the side surface 60c of the PIC 60. The side surface 90c of the fiber array 90 may be parallel to the side surface 80c of the encapsulating resin 80. The entire side surface 90c of the fiber array 90 is preferably bonded to the first bonding material 110.

The side surface 60c of the PIC 60 and the side surface 90c of the fiber array 90 are not perpendicular to a direction in which the optical signals are transmitted and received (a traveling direction of light). For this reason, it is possible to prevent the light emitted from one optical component from being reflected by a side surface of another optical component and returning in the direction of the one optical component.

In the optical-electrical integrated device 1, the first bonding material 110 is also disposed between the lower surface of the fiber array 90 and the upper surface of the first wiring board 10, and bonds the fiber array 90 and the first wiring board 10 together.

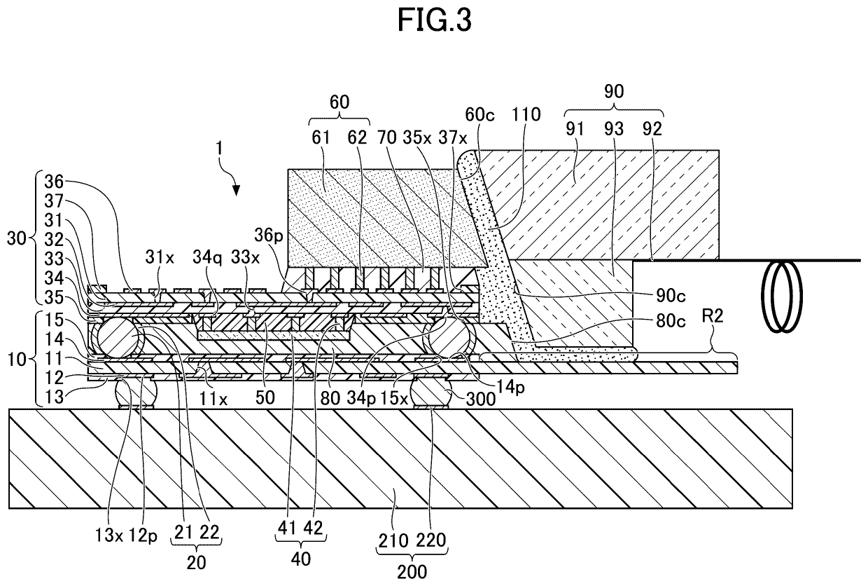

FIG. 3 is a cross sectional view illustrating an application example of the optical-electrical integrated device according to the first embodiment. As illustrated in FIG. 3, the optical-electrical integrated device 1 is mounted on a package substrate 200. Specifically, the package substrate 200 includes a main body 210, and pads 220 disposed on an upper surface of the main body 210. The pads 220 are electrically connected to the pads 12p of the optical-electrical integrated device 1 via bonding parts 300, such as solder balls or the like.

The package substrate 200 may be mounted with a processor, for example. The processor can be electrically connected to the semiconductor device 40 of the optical-electrical integrated device 1 via the package substrate 200.

A lower surface of the package substrate 200 is connected to a mounted circuit board or a printed circuit board (PCB), such as a motherboard or the like, for example. That is, the package substrate 200 is an interposer that bridges electrical interconnections between the optical-electrical integrated device 1 and another mounted board. The main body 210 of the package substrate 200 is a resin substrate or a silicon substrate formed with multilayer interconnects, for example. By using the package substrate 200, it is possible to increase the pitch even in a case where the pads of the optical-electrical integrated device 1 have a narrow pitch, and facilitate the electrical connection between the optical-electrical integrated device 1 and another mounted board.

An optical interconnection structure with a high reliability of optical coupling between the fiber array 90 and the PIC 60 is completed in the state of the optical-electrical integrated device 1, and does not depend on the package substrate 200. Accordingly, the optical-electrical integrated device 1 is easy to handle, and it is possible to improve a design flexibility of a packaging or mounting structure using the optical-electrical integrated device 1.

### Method for Manufacturing Optical-Electrical Integrated Device

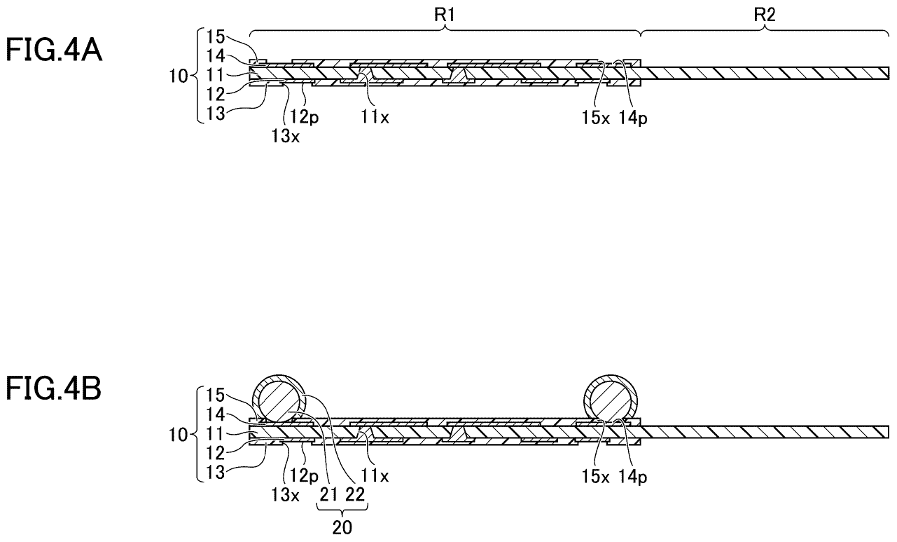

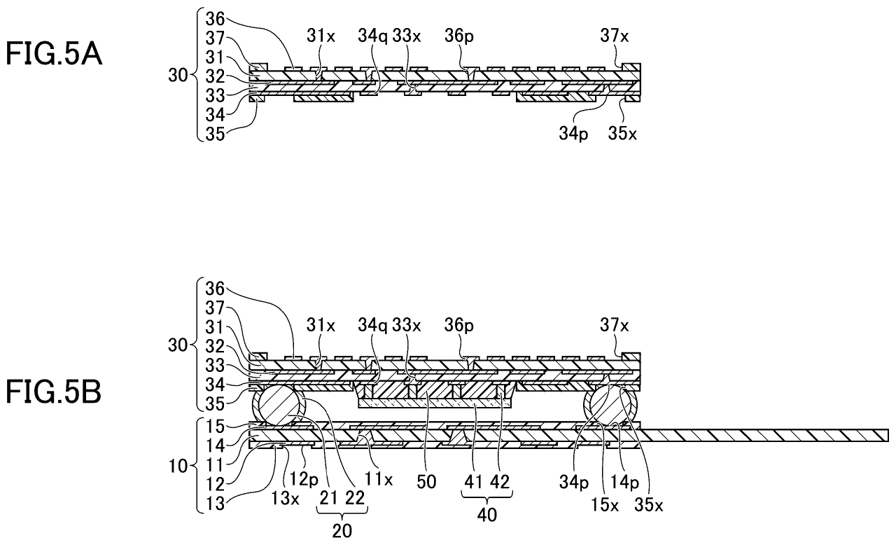

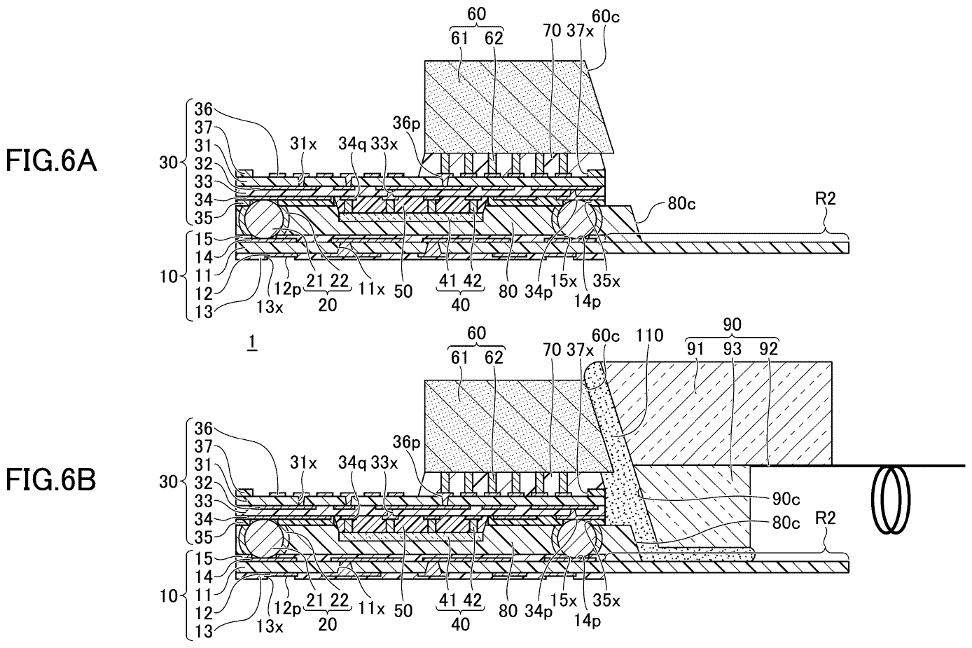

Next, a method for manufacturing the optical-electrical integrated device according to the first embodiment will be described. FIG. 4A, FIG. 4B, FIG. 5A, FIG. 5B, FIG. 6A, and FIG. 6B are diagrams illustrating examples of manufacturing processes of the optical-electrical integrated device according to the first embodiment.

First, in the process illustrated in FIG. 4A, the first wiring board 10 is manufactured. The first region R1 facing the second wiring board 30 and the second region R2 not facing the second wiring board 30 are defined in the first wiring board 10.

The first wiring board 10 can be formed using a known build-up method, for example. Specifically, the insulating layer 11 using a so-called glass epoxy substrate or the like is prepared. Then, the interconnect layer 14 is formed on the upper surface of the insulating layer 11. Next, the via holes 11x that expose the lower surface of the interconnect layer 14 are formed in the insulating layer 11, and the interconnect layer 12 is formed on the lower surface of the insulating layer 11. The interconnect layer 12 and the interconnect layer 14 are electrically connected through the via holes 11x in the insulating layer 11.

After forming the via holes 11x, a desmear process is preferably performed to remove residual resins adhered to the surface of the interconnect layer 14 exposed at the bottom of the via holes 11x. The via holes 11x can be formed by a laser machining technique using a CO₂ laser or the like, for example. The interconnect layers 12 and 14 may be formed using various interconnect forming methods, such as a semi-additive method, a subtractive method, or the like. The interconnect layers 12 and 14 can be formed by copper plating or the like, for example.

Next, the solder resist layer 13 covering the interconnect layer 12 is formed on the lower surface of the insulating layer 11, and the solder resist layer 15 covering the interconnect layer 14 is formed on the upper surface of the insulating layer 11. The solder resist layer 13 may be formed by coating a liquid or a paste of an insulating resin, such as a photosensitive epoxy-based resin or the like, on the lower surface of the insulating layer 11 by screen printing, roll coating, spin coating, or the like to cover the interconnect layer 12.

Similarly, the solder resist layer 15 may be formed by coating a liquid or a paste of an insulating resin, such as a photosensitive epoxy-based resin or the like, on the upper surface of the insulating layer 11 by a method similar to that described above for the solder resist layer 13 to cover the interconnect layer 14. Alternatively, instead of coating the liquid or the paste of the insulating resin, a film of the photosensitive epoxy-based resin or the like may be laminated on the upper surface of the insulating layer 11.

Then, the coated or laminated insulating resins are exposed and developed to form the openings 13x and 15x in the solder resist layers 13 and 15, respectively, and the pads 12p and 14p are formed using photolithography. Accordingly, the first wiring board 10 is completed. The openings 13x and 15x may be formed by a laser machining technique or a blast processing. The planar shape of each of the openings 13x and 15x may be a circular shape in the plan view, for example. Diameters of the openings 13x and 15x can be designed arbitrarily according to targets to which the connections are to be made.

Next, in the process illustrated in FIG. 4B, the connecting members 20 are placed on the pads 14p exposed inside the openings 15x in the solder resist layer 15 of the first wiring board 10. Then, the conductive material 22 constituting the connecting members 20 is heated to a predetermined temperature, melted, and thereafter cured to be bonded to the pads 14p. Portions of the core 21 constituting the connecting members 20 are in contact with the pads 14p. The connecting members 20 are arranged in the peripheral configuration, for example.

Next, in the process illustrated in FIG. 5A, the second wiring board 30 is manufactured. The second wiring board 30 can be manufactured using a known build-up method, for example. Specifically, the insulating layer 31 using a so-called glass epoxy substrate or the like is prepared, and the interconnect layer 32 is formed on the lower surface of the insulating layer 31. Next, the via holes 31x that expose the upper surface of the interconnect layer 32 is formed in the insulating layer 31, and the interconnect layer 36 is formed on the upper surface of the insulating layer 31. The interconnect layer 32 and the interconnect layer 36 are electrically connected through the via holes 31x in the insulating layer 31.

After the via holes 31x are formed, a desmear process is preferably performed to remove residual resins adhered to the surface of the interconnect layer 32 exposed at the bottom of the via holes 31x. The via holes 31x can be formed by a laser machining technique using a CO₂ laser or the like, for example. The interconnect layers 32 and 36 may be formed using various interconnect forming methods, such as the semi-additive method, the subtractive method, or the like.

Next, an insulating resin film of a thermosetting epoxy-based resin or the like is laminated on the lower surface of the insulating layer 31 to cover the interconnect layer 32, thereby forming the insulating layer 33. Alternatively, instead of laminating the insulating resin film, such as the thermosetting epoxy-based resin or the like, the insulating layer 33 may be formed by coating a liquid or a paste of the insulating resin, such as the thermosetting epoxy-based resin or the like, and thereafter curing the liquid or the paste of the insulating resin.

Next, the via holes 33x that penetrate the insulating layer 33 and expose the lower surface of the interconnect layer 32 are formed in the insulating layer. The via holes 33x can be formed by a laser machining technique using a CO₂ laser or the like, for example. After forming the via holes 33x, a desmear process is preferably performed to remove residual resins adhered to the surface of the interconnect layer 32 exposed at the bottom of the via holes 33x.

Next, the interconnect layer 34 is formed on the lower surface of the insulating layer 33. The interconnect layer 34 includes the via interconnect filling the inside of the via hole 33x and the interconnect pattern formed on the lower surface of the insulating layer 33. The interconnect layer 34 is electrically connected to the interconnect layer 32 exposed at the bottom of the via holes 33x. The interconnect layer 34 may be formed using various wiring forming methods, such as the semi-additive method, the subtractive method, or the like.

Next, similar to the solder resist layer 13 or the like of the first wiring board 10, the solder resist layer 35 covering the interconnect layer 34 is formed on the lower surface of the insulating layer 33, and the solder resist layer 37 covering the interconnect layer 36 is formed on the upper surface of the insulating layer 31. Then, similar to the openings 13x or the like of the first wiring board 10, openings 35x and 37x are formed in the solder resist layers 35 and 37, respectively, and pads 34p and 36p are formed using photolithography. Accordingly, the second wiring board 30 is completed. The planar shape of the second wiring board 30 may be a rectangular shape having a smaller area than that of the first wiring board 10 in the plan view, for example.

Next, in the process illustrated in FIG. 5B, the semiconductor device 40 including the main body 41 and the electrodes 42 is prepared, and the semiconductor device 40 is mounted on the second wiring board 30 so that the electrodes 42 are bonded to the pads 34q. Specifically, a paste of a solder material is coated on the pads 34q, for example. Then, the electrodes 42 of the semiconductor device 40 are aligned with the pads 34q, and the semiconductor device 40 is disposed on the second wiring board 30. Thereafter, the solder material is heated and melted by reflow or the like, and then solidified. The electrodes 42 are electrically connected to the pads 34q of the second wiring board 30 via the solder material.

Next, the second wiring board 30 is stacked on the first wiring board 10 with the semiconductor device 40 interposed therebetween so that the connecting members 20 are located at positions corresponding to the pads 34p. Thereafter, the conductive material 22 of the connecting members 20 is heated and melted by a heater or the like, and then solidified. Accordingly, lower sides of the cores 21 constituting the connecting members 20 are bonded to the pads 14p of the first wiring board 10, and upper sides of the cores 21 are bonded to the pads 34p of the second wiring board 30. That is, the first wiring board 10 and the second wiring board 30 are electrically connected to via the connecting members 20. In addition, a predetermined gap is secured between the first wiring board 10 and the second wiring board 30 by the cores 21 of the connecting members 20.

Next, in the process illustrated in FIG. 6A, the encapsulating resin 80 is formed, and then the PIC 60 is mounted. First, the encapsulating resin 80 is formed to fill a space between the first region R1 of the first wiring board 10 and the second wiring board 30, to cover the connecting members 20 and the semiconductor device 40, and to extend from the first region R1 to the second region R2. The encapsulating resin 80 is formed so that the side surface 80c is inclined toward the inside of the encapsulating resin 80 in the upward direction from the lower surface of the encapsulating resin 80. An insulating resin, such as a thermosetting epoxy-based resin or the like including a filler, for example, may be used for the encapsulating resin 80. The encapsulating resin 80 can be formed by transfer molding using an encapsulating mold, for example. The shape of the encapsulating resin 80 described above can be achieved by adjusting a shape of the encapsulating mold.

Next, the PIC 60 including the main body 61 and the electrodes 62, and having the inclined side surface 60c, is prepared. The PIC 60 having the inclined side surface 60c may be prepared by purchase or the like. Alternatively, the PIC 60 having the side surface 60c that is not inclined may be obtained and polished so that the side surface 60c becomes inclined.

Next, after the encapsulating resin 80 is cured, the PIC 60 is mounted on the second wiring board 30 on the side opposite from the first wiring board 10 so that the electrodes 62 are bonded to the pads 36p. Specifically, a paste of the solder material is coated on the pads 36p, for example. Then, the electrodes 62 of the PIC 60 and the pads 36p are aligned, and the PIC 60 is disposed on the second wiring board 30 on the side opposite from the first wiring board 10. Thereafter, the solder material is heated and melted by reflow or the like, and then solidified. Thus, the electrodes 62 of the PIC 60 are electrically connected to the pads 36p of the second wiring board 30 via the solder material.

Next, in the process illustrated in FIG. 6B, the fiber array 90 including the base 91, the plurality of optical fibers 92, and the lid 93, and having the inclined side surface 90c, is prepared. The fiber array 90 having the inclined side surface 90c may be prepared by purchase or the like. Alternatively, the fiber array 90 having the side surface 90c that is not inclined may be obtained and polished so that the side surface 90c becomes inclined.

Next, the fiber array 90 is disposed on the second region R2 of the first wiring board 10 with the lid 93 facing downward. Specifically, the side surface 90c of the fiber array 90 is disposed to face the side surface 60c of the PIC 60 via the uncured first bonding material 110 so that the optical fibers 92 are optically coupled to the optical waveguides of the PIC 60, respectively. The uncured first bonding material 110 is also disposed between the side surface 90c of the fiber array 90 and the side surface 80c of the encapsulating resin 80, and between the lower surface of the fiber array 90 and the first wiring board 10. In a state where the optical fibers 92 are positioned so as to be optically coupled to the optical waveguides of the PIC 60 by performing an active alignment, the uncured first bonding material 110 is cured.

The optical-electrical integrated device 1 is completed by the processes described above. The external connection terminals, such as the solder balls or the like, may be formed on the pads 12p of the first wiring board 10, if required.

As described above, in the optical-electrical integrated device 1, the fiber array 90 is fixed to the PIC 60 by the first bonding material 110 and is also fixed to the encapsulating resin 80 by the first bonding material 110. As a result, stress is unlikely to concentrate at a connecting part between the fiber array 90 and the PIC 60, and thus, it is possible to reduce the possibility of a break in the connecting part between the fiber array 90 and the PIC 60. That is, an optical interconnection structure having a high connection reliability can be achieved between the fiber array 90 and the PIC 60.

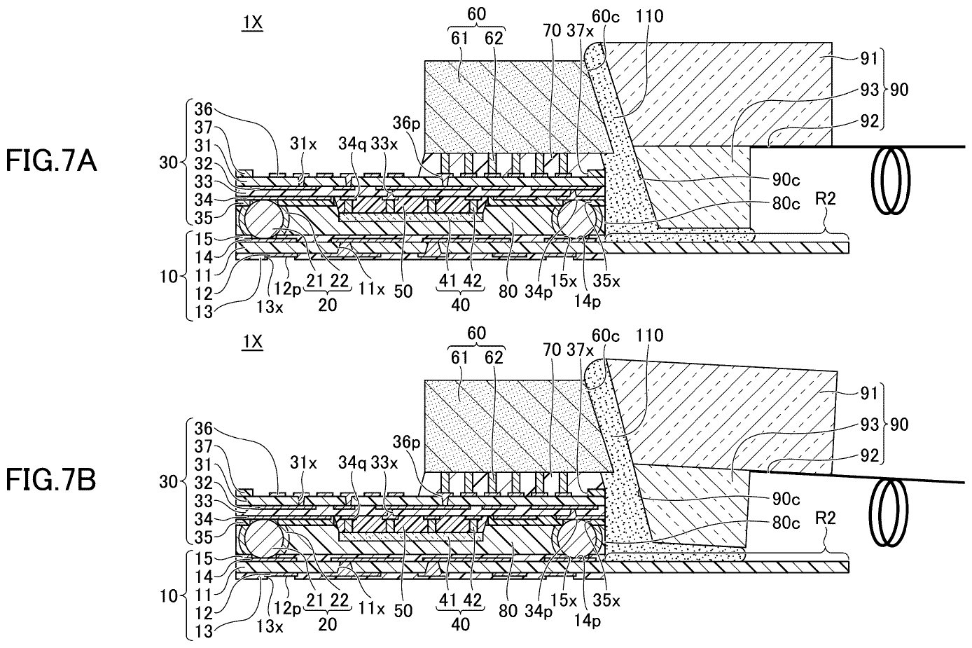

In the optical-electrical integrated device 1, the encapsulating resin 80 extends from the first region R1 to the second region R2, and the inclined side surface 80c of the encapsulating resin 80 is bonded to the first bonding material 110. According to such a structure, the fiber array 90 is unlikely to become inclined due to curing shrinkage of the first bonding material 110, and thus, an optical axis misalignment between the optical waveguide of the PIC 60 and the optical fiber 92 of the fiber array 90 can be prevented, as will be described hereinafter in more detail with reference to FIG. 7A and FIG. 7B.

FIG. 7A and FIG. 7B are cross sectional views illustrating an example of an optical-electrical integrated device according to a comparative example. FIG. 7A illustrates a state before the first bonding material 110 is cured, and FIG. 7B illustrates a state after the first bonding material 110 is cured.

An optical-electrical integrated device 1X illustrated in FIG. 7A and FIG. 7B differs from the optical-electrical integrated device 1 in that the encapsulating resin 80 does not extend from the first region R1 to the second region R2 and the side surface 80c of the encapsulating resin 80 is perpendicular to the lower surface of the encapsulating resin 80. In the optical-electrical integrated device 1X, the side surface 80c of the encapsulating resin 80 coincides with a side surface of the second wiring board 30.

In the optical-electrical integrated device 1X, an amount of the first bonding material 110 provided between the side surface 80c of the encapsulating resin 80 and the side surface 90c of the fiber array 90 is larger than an amount of the first bonding material 110 provided between the side surface 60c of the PIC 60 and the side surface 90c of the fiber array 90. The amount of the first bonding material 110 between the side surface 80c of the encapsulating resin 80 and the side surface 90c of the fiber array 90 increases toward the first wiring board 10.

According to such a structure, an amount of curing shrinkage occurring when the first bonding material 110 is cured is larger for the first bonding material 110 between the side surface 80c and the side surface 90c than in the first bonding material 110 between the side surface 60c and the side surface 90c. Further, because the amount of the first bonding material 110 between the side surface 80c and the side surface 90c increases toward the first wiring board 10, the amount of curing shrinkage of the first bonding material 110 between the side surface 80c and the side surface 90c increases toward the first wiring board 10.

As illustrated in FIG. 7A, before the first bonding material 110 is cured, the optical fibers 92 of the fiber array 90 are positioned so as to be optically coupled to the optical waveguides of the PIC 60 because the active alignment or the like is performed. However, due to the difference in the amount of curing shrinkage of the first bonding material 110 depending on the location as described above, when the first bonding material 110 is cured, the lower surface side of the fiber array 90 where the amount of the first bonding material 110 is large moves more in a direction approaching the encapsulating resin 80 than the upper surface side of the fiber array 90. For this reason, the fiber array 90 becomes inclined in the direction as illustrated in FIG. 7B. As a result, an optical axis misalignment occurs between the optical fibers 92 of the fiber array 90 and the optical waveguides of the PIC 60.

In contrast, in the optical-electrical integrated device 1, because the encapsulating resin 80 extends from the first region R1 to the second region R2, the amount of the first bonding material 110 between the side surface 80c of the encapsulating resin 80 and the side surface 90c of the fiber array 90 can be reduced compared to the optical-electrical integrated device 1X. Further, because the side surface 80c of the encapsulating resin 80 is inclined, the amount of the first bonding material 110 between the side surface 80c and the side surface 90c does not increase as the distance from the first wiring board 10 decreases. This prevents the lower surface side of the fiber array 90 from moving more toward the encapsulating resin 80 than the upper surface side of the fiber array 90 when the first bonding material 110 is cured. That is, because the inclination of the fiber array 90 due to the curing shrinkage of the first bonding material 110 is unlikely to occur, the optical axis misalignment between the optical waveguides of the PIC 60 and the optical fibers 92 of the fiber array 90 can be prevented.

### First Modification of First Embodiment

In a first modification of the first embodiment, an example of a wiring board in which a part of the first bonding material is replaced with the second bonding material will be described.

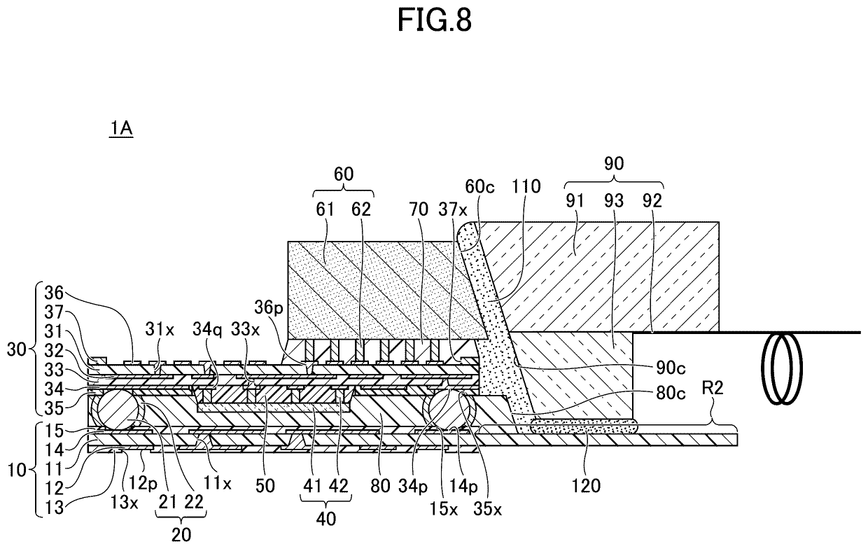

FIG. 8 is a cross sectional view illustrating an example of the optical-electrical integrated device according to the first modification of the first embodiment. As illustrated in FIG. 8, an optical-electrical integrated device 1A differs from the optical-electrical integrated device 1 in that the optical-electrical integrated device 1A includes a second bonding material 120 that is disposed between the fiber array 90 and the first wiring board 10 to bond the fiber array 90 and the first wiring board 10.

In the optical-electrical integrated device 1A, the side surface 90c of the fiber array 90 is bonded to the side surface 60c of the PIC 60 and the side surface 80c of the encapsulating resin 80 by the first bonding material 110. In addition, the lower surface of the fiber array 90 is bonded to the upper surface of the first wiring board 10 via the second bonding material 120.

The second bonding material 120 may be disposed in the entire region where the fiber array 90 and the second region R2 of the first wiring board 10 face each other, or may be disposed in a portion of the region where the fiber array 90 and the second region R2 of the first wiring board 10 face each other. For example, the second bonding material 120 may be disposed at four corners of the region where the fiber array 90 and the second region R2 of the first wiring board 10 face each other. In the illustrated example, the second bonding material 120 is in contact with the first bonding material 110, but the second bonding material 120 may not be in contact with the first bonding material 110. An ultraviolet curable epoxy-based resin, a thermosetting epoxy-based resin, or the like can be used for the second bonding material 120. The same material or different materials may be used for the first bonding material 110 and the second bonding material 120.

As described above, in the optical-electrical integrated device 1A, the fiber array 90 is fixed to the PIC 60 by the first bonding material 110 and is also fixed to the encapsulating resin 80 by the first bonding material 110, similar to the optical-electrical integrated device 1. Moreover, in the optical-electrical integrated device 1A, the encapsulating resin 80 extends from the first region R1 to the second region R2, and the inclined side surface 80c of the encapsulating resin 80 is bonded to the first bonding material 110, similar to the optical-electrical integrated device 1. Accordingly, the optical-electrical integrated device 1A can obtain the same effects as those obtainable by the optical-electrical integrated device 1.

Further, in the optical-electrical integrated device 1A, the use of the first bonding material 110 and the second bonding material 120 can improve the design flexibility. For example, because the second bonding material 120 is located at a position where the optical signals transmitted and received between the PIC 60 and the fiber array 90 do not pass through, the transmittance of the second bonding material 120 with respect to the wavelength of the optical signal may be lower than the transmittance of the first bonding material 110 with respect to the wavelength of the optical signal. As a result, an expanded selection of the second bonding material 120 becomes available, and the second bonding material 120 can be selected so that an adhesive strength between the fiber array 90 and the first wiring board 10 becomes higher than an adhesive strength between the fiber array 90 and the PIC 60, for example. This is particularly effective in a case where the first bonding material 110 having a high transmittance with respect to the wavelength of the optical signals transmitted and received between the PIC 60 and the fiber array 90 has a low bonding strength. The adhesive strength can be defined as a value obtained by dividing a load, applied to two components bonded by a bonding material when the bonded portion breaks, by a bonding area between the two components.

### Second Modification of First Embodiment

In a second modification of the first embodiment, an example of a wiring board in which the side surface 60c and the side surface 90c are not inclined will be described.

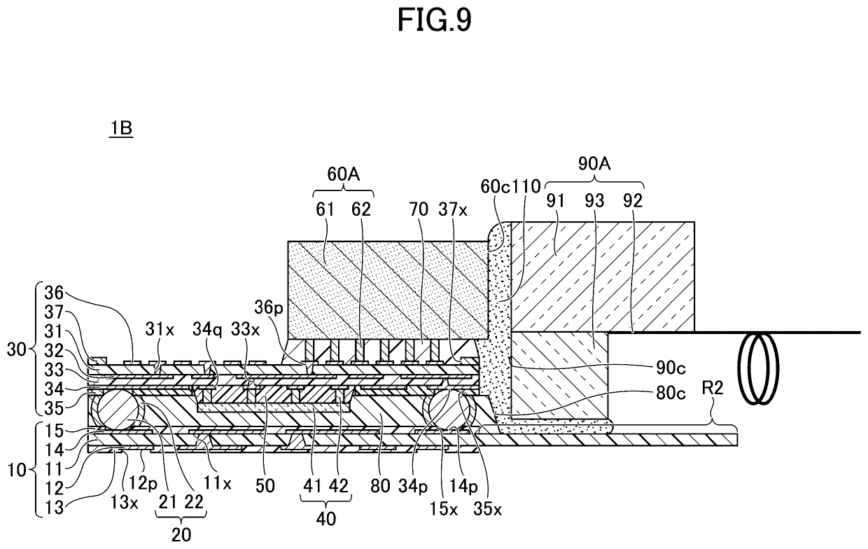

FIG. 9 is a cross sectional view illustrating an example of the optical-electrical integrated device according to the second modification of the first embodiment. As illustrated in FIG. 9, an optical-electrical integrated device 1B differs from the optical-electrical integrated device 1 in that the PIC 60 and the fiber array 90 are replaced with a photonic integrated circuit (PIC) 60A and a fiber array 90A, respectively.

The side surface 60c of the PIC 60A and the side surface 90c of the fiber array 90A are not inclined surfaces. The angle formed by the lower surface of the PIC 60A and the side surface 60c may be 88° or greater and 92° or less, for example. The angle formed by the lower surface of the fiber array 90A and the side surface 90c may be, 88° or greater and 92° or less, for example.

In the optical-electrical integrated device 1B, the fiber array 90A is fixed to the PIC 60A by the first bonding material 110 and is also fixed to the encapsulating resin 80 by the first bonding material 110, similar to the optical-electrical integrated device 1. In the optical-electrical integrated device 1B, the encapsulating resin 80 extends from the first region R1 to the second region R2, and the inclined side surface 80c of the encapsulating resin 80 is bonded to the first bonding material 110, similar to the optical-electrical integrated device 1. Accordingly, the optical-electrical integrated device 1B can obtain the same effects as those obtainable by the optical-electrical integrated device 1.

As described above, the side surface 60c of the PIC 60A and the side surface 90c of the fiber array 90A may not inclined surfaces. Of course, the second bonding material 120 may be used to fix the fiber array 90A and the first wiring board 10.

### Third Modification of First Embodiment

In a third modification of the first embodiment, an example in which a connector 150 is disposed in place of the fiber array 90 is illustrated.

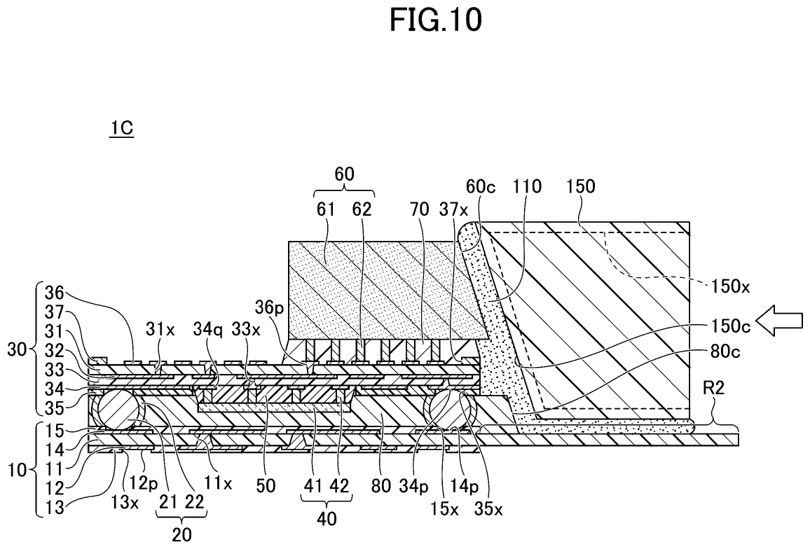

FIG. 10 is a cross sectional view illustrating an example of the optical-electrical integrated device according to the third modification of the first embodiment. As illustrated in FIG. 10, in an optical-electrical integrated device 1C, the connector 150 is disposed adjacent to the PIC 60 via the first bonding material 110. The connector 150 is a typical example of an optical component according to the present invention.

A side surface 150c of the connector 150, bonded to the first bonding material 110, is an inclined surface inclined toward an outside of the connector 150 in an upward direction from a lower surface of the connector 150. An angle formed by an upper surface and the side surface 150c of the connector 150 can be 80° or greater and 85° or less, for example. The side surface 150c of the connector 150 is parallel to the side surface 60c of the PIC 60, for example.

The side surface 150c of the connector 150 is bonded to the side surface 60c of the PIC 60 and the side surface 80c of the encapsulating resin 80 by the first bonding material 110. Further, the lower surface of the connector 150 is bonded to the upper surface of the first wiring board 10 by the first bonding material 110. The entire side surface 150c of the connector 150 is preferably bonded to the first bonding material 110.

The connector 150 is a female connector and can be formed of a transparent resin or the like, for example. The connector 150 may be formed of an opaque resin, and openings through which the optical signals can be transmitted and received may be provided in regions facing the optical waveguides of the PIC 60.

The connector 150 has an inserting portion 150x that opens on the opposite side of the PIC 60, and can be connected to a fiber array including optical fibers. When the connector 150 and the fiber array are connected, the PIC 60 can transmit and receive the optical signals to and from the optical fibers. For example, by inserting a male connector joined to the fiber array into the inserting portion 150x in a direction of an arrow in FIG. 10, the optical fibers of the fiber array and the optical waveguides of the PIC 60 are aligned to face one another, and the optical fibers and the optical waveguides can be optically coupled. The connector 150 may be a male connector, and the connector connected to the fiber array may be a female connector.

In the optical-electrical integrated device 1C, the connector 150 is fixed to the PIC 60 by the first bonding material 110 and is also fixed to the encapsulating resin 80 by the first bonding material 110. In the optical-electrical integrated device 1C, the encapsulating resin 80 extends from the first region R1 to the second region R2, and the inclined side surface 80c of the encapsulating resin 80 is bonded to the first bonding material 110, similar to the optical-electrical integrated device 1. Accordingly, the optical-electrical integrated device 1C can obtain the same effects as those obtainable by the optical-electrical integrated device 1.

As described above, the optical component according to the present invention is not limited to the fiber array 90, and may be the connector 150 or the like as long as the optical component is a component that is disposed adjacent to the PIC 60 via the first bonding material 110 and contributes to enabling the transmission and reception of the optical signals to and from the PIC 60.

In the case where the optical component according to the present invention is the connector 150, stress may be repeatedly applied to the connecting part between the connector 150 and the PIC 60 when the fiber array or the like is attached to and detached from the connector 150. For this reason, there is a great technical significance in fixing the connector 150 to the PIC 60 by the first bonding material 110 and also fixing the connector 150 to the encapsulating resin 80 by the first bonding material 110 to reduce the stress applied to the connecting part between the connector 150 and the PIC 60. Of course, the second bonding material 120 may be used to fix the connector 150 and the first wiring board 10.

According to the disclosed technology, it is possible to provide an optical-electrical integrated device having an optical coupling structure with a high reliability of optical coupling.

Although the modifications are numbered with, for example, “first,” “second,” or “third,” the ordinal numbers do not imply priorities of the modifications. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An optical-electrical integrated device comprising:
a first wiring board;
a second wiring board facing a first region of the first wiring board and electrically connected to the first wiring board via a connecting member disposed in the first region;
a semiconductor device mounted on the first wiring board or the second wiring board;
an encapsulating resin filled between the first region of the first wiring board and the second wiring board to cover the connecting member and the semiconductor device;
a photonic integrated circuit mounted on a side of the second wiring board opposite from the first wiring board and electrically connected to the semiconductor device;
an optical component, disposed adjacent to the photonic integrated circuit on a second region of the first wiring board not facing the second wiring board, and configured to enable transmission and reception of optical signals to and from the photonic integrated circuit; and
a first bonding material, disposed between the photonic integrated circuit and the optical component and between the encapsulating resin and the optical component, bonding the photonic integrated circuit, the optical component, and the encapsulating resin together, wherein:
the encapsulating resin extends from the first region to the second region, and
a first side surface of the encapsulating resin bonded to the first bonding material is an inclined surface inclined toward an inside of the encapsulating resin in an upward direction from a lower surface of the encapsulating resin.

2. The optical-electrical integrated device as claimed in claim 1, wherein:
a second side surface of the photonic integrated circuit bonded to the first bonding material is an inclined surface inclined toward an inside of the photonic integrated circuit in an upward direction from a lower surface of the photonic integrated circuit, and
a third side surface of the optical component bonded to the first bonding material is an inclined surface inclined toward an outside of the optical component in an upward direction from a lower surface of the optical component.

3. The optical-electrical integrated device as claimed in claim 2, wherein the second side surface and the third side surface are parallel to each other.

4. The optical-electrical integrated device as claimed in claim 3, wherein the first side surface, the second side surface, and the third side surface are parallel to one another.

5. The optical-electrical integrated device as claimed in claim 1, wherein the first bonding material is also disposed between the optical component and the first wiring board to bond the optical component and the first wiring board.

6. The optical-electrical integrated device as claimed in claim 1, further comprising:
a second bonding material disposed between the optical component and the first wiring board and bonding the optical component and the first wiring board.

7. The optical-electrical integrated device as claimed in claim 6, wherein an adhesive strength between the optical component and the first wiring board is higher than an adhesive strength between the optical component and the photonic integrated circuit.

8. The optical-electrical integrated device as claimed in claim 6, wherein a transmittance of the second bonding material with respect to a wavelength of the optical signals is lower than a transmittance of the first bonding material with respect to the wavelength of the optical signals.

9. The optical-electrical integrated device as claimed in claim 1, wherein:
the optical component includes a plurality of optical fibers,
the photonic integrated circuit is configured to transmit and receive the optical signals to and from the plurality of optical fibers.

10. The optical-electrical integrated device as claimed in claim 1, wherein:
the optical component is a connector connectable to a fiber array including a plurality of optical fibers, and
the photonic integrated circuit is configured to transmit and receive the optical signals to and from the plurality of optical fibers when the connector and the fiber array are connected.
